(19) United States
(12) Patent Application Publication
(10) Pub. No.: US 2020/0211810 A1
(43) Pub. Date: Jul. 2, 2020

(54) APPARATUS FOR GENERATING A MULTIPLICITY OF PARTICLE BEAMS, AND MULTI-BEAM PARTICLE BEAM SYSTEMS

(71) Applicant: Carl Zeiss Microscopy GmbH, Jena (DE)

(72) Inventor: Dirk Zeidler, Oberkochen (DE)

(21) Appl. No.: 16/725,944

(22) Filed: Dec. 23, 2019

(30) Foreign Application Priority Data
Dec. 29, 2018 (DE) 10 2018 133 703.5

(51) Int. Cl. H01J 37/10; H01J 37/21; H01J 37/24

(52) U.S. Cl. CPC H01J 37/10; H01J 37/21; H01J 2237/04926; H01J 2237/0453; H01J 2237/21; H01J 37/243

(57) ABSTRACT

An apparatus for generating a multiplicity of particle beams includes a particle source, a first multi-aperture plate with a multiplicity of openings, a second multi-aperture plate with a multiplicity of openings, a first particle lens, a second particle lens, a third particle lens 23, and a controller, which supplies each of the first particle lens, the second particle lens and the third particle lens with an adjustable excitation.

### CROSS-REFERENCE TO RELATED APPLICATION

This application claims priority under 35 U.S.C. § 119 to German Application No. 10 2018 133 703.5, filed Dec. 29, 2018. The content of this application is hereby incorporated by reference in its entirety.

### FIELD

The disclosure relates to an apparatus for generating a multiplicity of particle beams and a multi-beam particle beam system working with a multiplicity of particle beams.

### BACKGROUND

WO 2005/024881 discloses a multi-beam particle beam system including a particle source for generating particles that strike a multi-aperture plate. The multi-aperture plate includes a multiplicity of openings, through which the particles pass and which form a multiplicity of particle beams in the beam path downstream of the multi-aperture plate. Further, the multi-beam particle beam system includes an objective lens which focuses the individual particle beams at an object. The individual particle beams are focussed at the object by virtue of the particle beams each imaging the particle source on the surface of the object by way of the multi-beam particle beam system. The quality of the focus generated at the object by the individual particle beam depends on the quality of the imaging of the particle source on the object. This quality is impaired by various factors. One of these factors is electrostatic repulsion between the particles forming the individual particle beams.

In order to reduce this electrostatic repulsion of the particles forming the particle beams, US 2017/0025241 A1 and US 2017/0025243 A1 propose, in the beam path upstream of the multi-aperture plate whose openings define the individual particle beams, to dispose a further multi-aperture plate closer to the source, the openings of the further multi-aperture plate being passed through by the particles that subsequently form the particle beams, but at least some of the particles are not allowed to pass through openings and subsequently would not contribute to the formation of the particle beams. This reduces the number of particles present in the beam path between the two multi-aperture plates at any given time without reducing the intensity of the individual particle beams. Accordingly, Coulomb repulsion, which acts on the particles subsequently forming the particle beams, is reduced in this region of the beam path. Consequently, this can theoretically improve the quality of the imaging of the particle source on the surface of the object.

### SUMMARY

It was found that the concept of disposing a further multi-aperture plate in the beam path between the particle source and the multi-aperture plate forming the multiplicity of particle beams is difficult to realize in practice.

The present disclosure proposes an apparatus for generating a multiplicity of particle beams, which includes a further multi-aperture plate in the beam path between a particle source and a multi-aperture plate for generating a multiplicity of particle beams and which is comparatively easy to handle.

According to exemplary embodiments of the disclosure, an apparatus for generating a multiplicity of particle beams includes a particle source, a first multi-aperture plate, which includes a multiplicity of openings, and a second multi-aperture plate, which includes a multiplicity of openings and which is disposed in a beam path of the apparatus between the particle source and the first multi-aperture plate. The particle source is configured to generate particles that pass through the multiplicity of openings in the second multi-aperture plate during the operation of the apparatus. Here, it is desirable for at least some of the particles passing through the multiplicity of openings in the second multi-aperture plate to likewise pass through openings in the first multi-aperture plate in order to form the multiplicity of particle beams in the beam path downstream of the first multi-aperture plate. It was found that it is difficult to position the first and the second multi-aperture plates relative to one another and to dispose the openings in the first or second multi-aperture plate in such a way that the apparatus is comparatively deasy to handle and the individual particle beams have high beam intensities.

According to exemplary embodiments of the disclosure, an apparatus for generating a multiplicity of particle beams includes a first particle lens, which is disposed in the beam path between the second multi-aperture plate and the first multi-aperture plate, a second particle lens, which is disposed in the beam path between the first particle lens and the first multi-aperture plate, and a controller, which is configured to supply the first particle lens with an adjustable excitation and likewise supply the second particle lens with an adjustable excitation. In particular, the controller can be embodied in such a way that the excitation supplied to the first particle lens is independently adjustable from the excitation supplied to the second particle lens.

The particles generated by the particle source can strike the second multi-aperture plate as a divergent beam. The second multi-aperture plate can be formed from a plane plate, in which the openings are provided. However, the second multi-aperture plate can also be a curved plate, in which the openings are provided.

The first multi-aperture plate can be a plane plate, in which the openings are provided. However, the first multi-aperture plate can also be a curved plate, in which the openings are provided.

The particles passing through the openings in the second multi-aperture plate already form particle beams, each of which should pass through one of the openings in the first multi-aperture plate. The openings in the second multi-aperture plate are disposed at given spacings from one another. These spacings define the distances in the plane of the first multi-aperture plate of the particle beams formed by the opening in the second multi-aperture plate. In the plane of the first multi-aperture plate, these spacings between the particle beams generally do not correspond to the spacings between the openings in the first multi-aperture plate. However, it is possible to set the excitations of the first and the second particle lens in such a way that this correspondence is obtained and that particles that have passed through openings in the second multi-aperture plate are also able, in principle, to pass through openings in the first multi-aperture plate.

The change in the excitations of the first and second particle lens, carried out in view thereof, generally also leads to a change in the divergence of the particle beams striking the first multi-aperture plate from the particles that have passed through the openings in the second multi-aperture plate. Then, this change in the divergence, in turn, leads to a change in the divergence of the particle beams formed in the beam path downstream of the first multi-aperture plate. It may be desirable to set this divergence to a target value and also maintain this value when the excitations of the first and the second particle lens are altered. However, precisely this is possible because setting the excitations of the first and the second particle lens offers two degrees of freedom, which can be used to facilitate setting of the divergence of the particle beams formed in the beam path downstream of the first multi-aperture plate independently of setting of the spacings of the particle beams striking the first multi-aperture plate.

In general, changes in the excitations of the first and the second particle lens also cause an arrangement pattern of the particle beams passing through the openings in the second multi-aperture plate to rotate about an optical axis of the first and/or second particle lens in the plane of the first multi-aperture plate. However, the arrangement pattern of the particle beams striking the first multi-aperture plate should correspond to the arrangement pattern of the openings in the first multi-aperture plate so that particle beams with a high beam intensity are generated in the beam path downstream of the first multi-aperture plate. A possibly changing rotation of the arrangement pattern of the particle beams in the plane of the first multi-aperture plate can be achieved by virtue of, for example, the first multi-aperture plate and the second multi-aperture plate being twisted relative to one another. This can be brought about by mechanical actuators, for example.

According to further exemplary embodiments, the apparatus for generating a multiplicity of particle beams further includes a third particle lens, which is disposed in the beam path between the second particle lens and the first multi-aperture plate, with the controller further being configured to supply the third particle lens with an adjustable excitation. In particular, the excitation of the third particle lens can be adjustable independently of the excitation of the first particle lens and/or independently of the excitation of the second particle lens. The adjustability of the excitation of the third particle lens offers a third degree of freedom for forming the pattern of the particle beams incident in the plane of the first multi-aperture plate such that these are adjustable in view of their spacings from one another, in view of their divergence and in view of the twist about the optical axes of the particle lenses.

According to exemplary embodiments, diameters of the openings in the first multi-aperture plate and diameters of the openings in the second multi-aperture plate are matched to one another in such a way that some of the particles that pass through the openings in the second multi-aperture plate pass through the openings in the first multi-aperture plate and other particles strike the first multi-aperture plate and do not pass through the openings in the first multi-aperture plate. This means that the cross sections of the particle beams formed in the beam path downstream of the first multi-aperture plate are defined by the forms of the openings in the first multi-aperture plate. Further multi-aperture plates may be disposed in the beam path downstream of the first multi-aperture plate, the further multi-aperture plates further defining the particle beams by virtue of the the particle beams only passing through the further multi-aperture plate in part. However, the further multi-aperture plates may also have openings whose diameters are chosen to be so large that the particle beams pass therethrough in their entirety and the openings do not directly influence the particle beams in respect of the particles contained in the particle beams. However, such openings may provide electric potentials or magnetic fields in order to influence the particle beams passing through the openings in respect of the trajectories of the particles forming the particle beams. In particular, effects such as those of a focusing or diverging lens or/and of a deflector or/and of a stigmator can be provided on the individual particle beams as a result thereof.

According to exemplary embodiments, the controller is configured to set the excitations of the first, second and third particle lens in such a way that the particle beams respectively pass through the openings in the first multi-aperture plate in a direction that lies in a plane containing a center of the opening in the first multi-aperture plate which is passed though by the respective particle beam and containing an optical axis of the first, second or third particle lens.

This means that the particles that form the particle beams formed in the beam path downstream of the first multi-aperture plate extend in a straight line, apart from a possible divergence or convergence, and do not travel on spiral trajectories, for instance, when they pass through the openings in the first multi-aperture plate. However, should the particles in the beam path downstream of the first multi-aperture plate be exposed to further magnetic fields, the particles can move along spiral trajectories again.

According to further exemplary embodiments, the apparatus further includes a first stigmator, which is disposed in the beam path between the second multi-aperture plate and the first multi-aperture plate, with the controller further being configured to supply the first stigmator with an adjustable excitation. According to further exemplary embodiments herein, the apparatus further includes a second stigmator, which is disposed in the beam path between the first stigmator and the first multi-aperture plate, with the controller further being configured to supply the second stigmator with an adjustable excitation which, in particular, can be set independently from the excitation of the first stigmator.

Depending on whether one or two stigmators are provided, these offer one or two further degrees of freedom to influence the pattern of the arrangement of impingement locations of the particle beams, passing through the openings in the second multi-aperture plate, in the plane of the first multi-aperture plate and, in particular, to compensate possible imaging aberrations of the first, second or third particle lens.

According to further exemplary embodiments, the apparatus further includes a fourth particle lens, which is disposed in the beam path between the particle source and the second multi-aperture plate, with the controller further being configured to supply the fourth particle lens with an adjustable excitation. A change in the excitation of the fourth particle lens leads to a change in the divergence of the particle beam generated by the particle source and striking the second multi-aperture plate. A change in this divergence leads, further, to a change in the particle density of the particles passing through the openings in the second multi-aperture plate and consequently leads to a change in the beam intensities or beam currents of the particle beams formed by the openings in the second multi-aperture plate. Since particles of these particle beams, in turn, pass through the openings in the first multi-aperture plate and form the particle beams formed in the beam path downstream of the first multi-aperture plate, the change in the excitation of the fourth particle lens changes the beam intensities or beam currents of the particle beams formed in the beam path downstream of the first multi-aperture plate. The possibility of changing the intensities of the particle beams generated by the apparatus may be desirable when the apparatus is used in practice.

Since the change in the intensities of the generated particle beams by way of the change in the excitation of the fourth particle lens leads to a change in the divergence of the particles striking the second multi-aperture plate, this leads to a change in the arrangement pattern of the locations at which the particle beams formed by the openings in the second multi-aperture plate strike the first multi-aperture plate. However, these changes can be compensated by corresponding changes in the excitations of the first, second and third particle lens such that the particle beams formed in the beam path downstream of the first multi-aperture plate continue to be formed by the openings in the first multi-aperture plate.

According to further embodiments of the disclosure, a multi-beam particle beam system is provided, including the apparatus for generating a multiplicity of particle beams, as explained above, and an objective lens for focusing the particle beams at an object. According to exemplary embodiments, the multi-beam particle beam system is a multi-beam particle beam microscope including a detector arrangement for detecting signals that are generated by the particle beams at the object.

### BRIEF DESCRIPTION OF THE DRAWINGS

Exemplary embodiments of the disclosure are explained below with reference to the attached figures, in which:

FIG. 1 shows a schematic illustration of a multi-beam particle beam system according to one embodiment; and

FIG. 2 shows a schematic cross-sectional illustration of an apparatus for generating a multiplicity of particle beams according to one embodiment.

### EXEMPLARY EMBODIMENTS OF THE DISCLOSURE

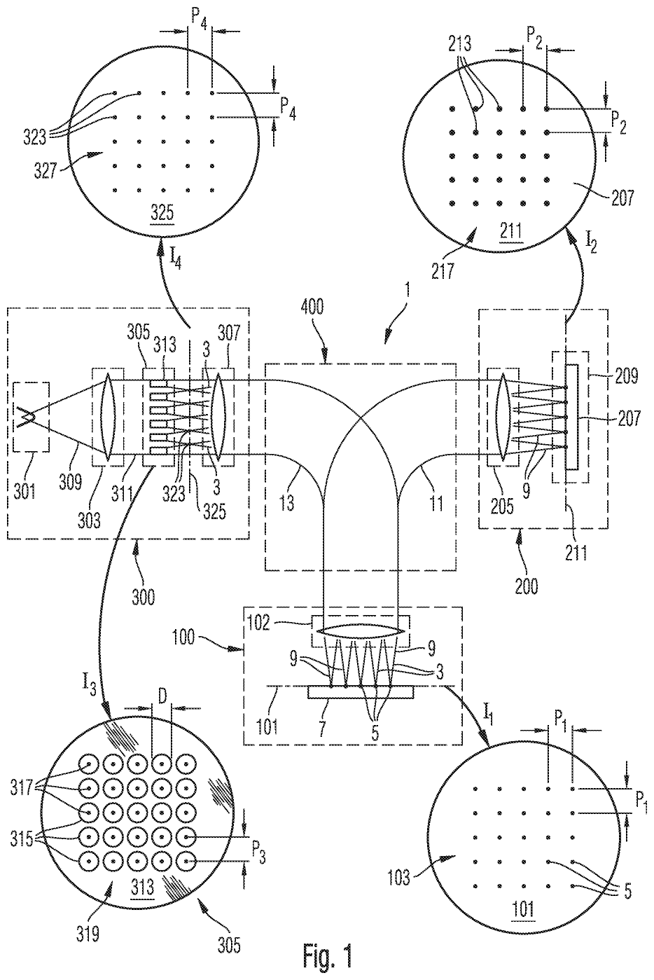

FIG. 1 is a schematic illustration of a multi-beam particle beam system 1, which works with a multiplicity of particle beams. The multi-beam particle beam system 1 generates a multiplicity of particle beams which strike an object to be examined in order to generate there electrons which emanate from the object and are subsequently detected. The multi-beam particle beam system 1 is of the scanning electron microscope (SEM) type, which uses a plurality of primary electron beams 3 which are incident at locations 5 on a surface of the object 7 and generate a plurality of electron beam spots there. The object 7 to be examined can be of any desired type and include for example a semiconductor wafer, a biological sample, and an arrangement of miniaturized elements or the like. The surface of the object 7 is arranged in an object plane 101 of an objective lens 102 of an objective lens system 100.

The enlarged excerpt I1 in FIG. 1 shows a plan view of the object plane 101 having a regular rectangular array 103 of impingement locations 5 formed in the plane 101. In FIG. 1, the number of impingement locations is 25, which form a 5×5 array 103. The number 25 of impingement locations is a small number chosen for reasons of simplified illustration. In practice, the number of beams or impingement locations can be chosen to be significantly greater, such as, for example, 20×30, 100×100 and the like.

In the embodiment illustrated, the array 103 of impingement locations 5 is a substantially regular rectangular array having a constant spacing P1 between adjacent impingement locations. Exemplary values of the spacing P1 are 1 micrometre, 10 micrometres and 40 micrometres. However, it is also possible for the array 103 to have other symmetries, such as a hexagonal symmetry, for example.

A diameter of the beam spots formed in the object plane 101 can be small. Exemplary values of the diameter are 1 nanometre, 5 nanometres, 100 nanometres and 200 nanometres. The focusing of the particle beams 3 for shaping the beam spots 5 is implemented by the objective lens system 100.

The particles striking the object generate electrons that emanate from the surface of the object 7. The electrons emanating from the surface of the object 7 are shaped by the objective lens 102 to form electron beams 9. The inspection system 1 provides an electron beam path 11 in order to feed the multiplicity of electron beams 9 to a detection system 200. The detection system 200 includes an electron optical unit having a projection lens 205 to direct the electron beams 9 onto an electron multi-detector 209.

The excerpt 12 in FIG. 1 shows a plan view of a plane 211, in which lie individual detection regions on which the electron beams 9 are incident at locations 213. The impingement locations 213 lie in an array 217 with a regular spacing P2 from one another. Exemplary values of the spacing P2 are 10 micrometres, 100 micrometres and 200 micrometres.

The primary electron beams 3 are generated in an apparatus 300, illustrated very schematically in FIG. 1, for generating a multiplicity of particle beams, the apparatus including at least one electron source 301, at least one collimation lens 303 and a multi-aperture plate arrangement 305 and, optionally, a field lens 307. The electron source 301 generates a diverging electron beam 309, which is collimated by the at least one collimation lens 303 to form a beam 311 which illuminates the multi-aperture plate arrangement 305.

The excerpt 13 in FIG. 1 shows a plan view of the multi-aperture plate arrangement 305. The multi-aperture plate arrangement 305 includes a multi-aperture plate 313, which has a plurality of openings 315 formed therein. Midpoints 317 of the openings 315 are arranged in an array 319 corresponding to the array 103 formed by the beam spots 5 in the object plane 101. A spacing P3 between the midpoints 317 of the openings 315 can have exemplary values of 5 micrometres, 100 micrometres and 200 micrometres. The diameters D of the openings 315 are smaller than the spacing P3 between the midpoints of the openings. Exemplary values of the diameters D are 0.2×P3, 0.4×P3 and 0.8×P3.

Electrons of the illuminating beam 311 pass through the openings 315 and form electron beams 3. Electrons of the illuminating beam 311 which strike the plate 313 are absorbed by the latter and do not contribute to the formation of the electron beams 3.

The multi-aperture plate arrangement 305 can focus the electron beams 3 in such a way that beam foci 323 are formed in a plane 325. A diameter of the foci 323 can be for example 10 nanometres, 100 nanometres and 1 micrometre.

The field lens 307 and the objective lens 102 provide a first imaging particle optical unit for imaging the plane 325 in which the foci are formed onto the object plane 101, such that an array 103 of impingement locations 5 or beam spots is formed there on the surface of the object 7.

The objective lens 102 and the projection lens arrangement 205 provide a second imaging particle optical unit for imaging the object plane 101 onto the detection plane 211. The objective lens 102 is thus a lens which is part of both the first and the second particle optical unit, while the field lens 307 belongs only to the first particle optical unit and the projection lens 205 belongs only to the second particle optical unit.

A beam switch 400 is arranged in the beam path of the first particle optical unit between the multi-aperture plate arrangement 305 and the objective lens system 100. The beam switch 400 is also part of the second particle optical unit in the beam path between the objective lens system 100 and the detection system 200.

Further information concerning such multi-beam particle beam systems and components used therein, such as, for instance, particle sources, multi-aperture plates and lenses, can be obtained from the international patent applications WO 2005/024881, WO 2007/028595, WO 2007/028596 and WO 2007/060017, and the German patent applications having the application numbers DE 10 2013 016 113 A1, DE 10 2013 014 976 A1 and DE 10 2014 008 083 A1, the disclosure of which in the full scope thereof is incorporated by reference in the present application.

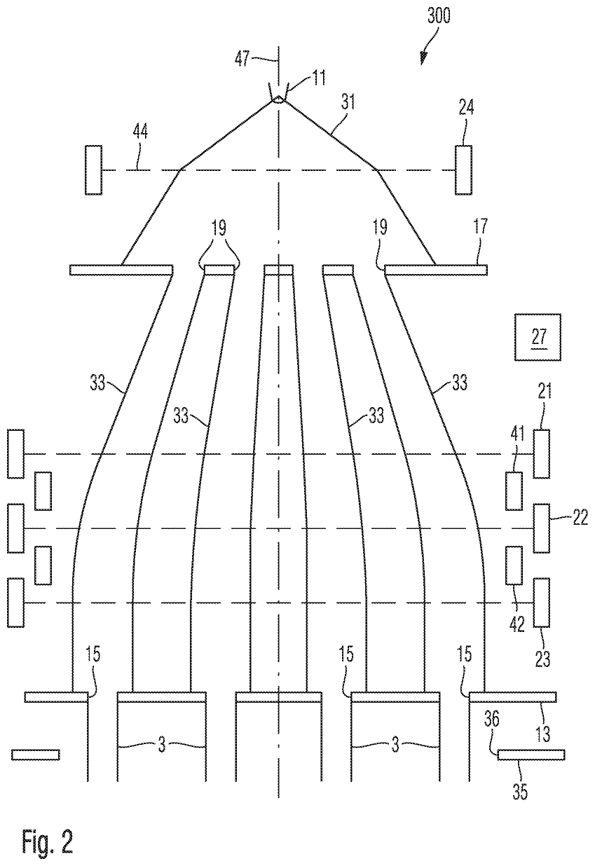

An apparatus 300 for generating a multiplicity of particle beams 3 is illustrated schematically in a longitudinal section in FIG. 2. The apparatus 300 includes a particle source 11 and a first multi-aperture plate 13 with a multiplicity of openings 15 and a second multi-aperture plate 17 with a multiplicity of openings 19. A first particle lens 21 is disposed in a beam path between the second multi-aperture plate 17 and the first multi-aperture plate 13. A second particle lens 22 is disposed in the beam path between the first particle lens 21 and the first multi-aperture plate 13. A third particle lens 23 is disposed in the beam path between the second particle lens 22 and the first multi-aperture plate 13. A fourth particle lens 24 is disposed in the beam path between the particle source 11 and the second multi-aperture plate 17.

The excitations of the first, second, third and fourth particle lens, 21, 22, 23 and 24, respectively, are adjustable by a controller 27, which supplies adjustable excitations by way of feed lines to the particle lenses 21, 22, 23 and 24 in each case. The particle lenses 21, 22, 23 and 24 can be magnetic particle lenses that have a focusing effect on particle beams that pass through the respective particle lens. The strength of the focusing effect corresponds to the excitation supplied to the respective lens, i.e., the supplied excitation current in the case of the magnetic particle lens. However, the particle lenses may also be electrostatic particle lenses that provide electrostatic fields, the latter providing a focusing or diverging effect for the particle beams passing through the respective particle lens.

These effects are generated by electrostatic fields, adjustable voltages that are applied to electrodes of the respective particle lens being supplied to the lenses by the controller for the purposes of exciting the electrostatic fields. The particle lenses may each also provide a combination of magnetic and electrostatic fields in order to provide focusing or diverging effects on the particle beams passing through the respective particle lens.

During operation, the particle source 11 generates a divergent particle beam 31, which passes through the fourth particle lens 24 and strikes the second multi-aperture plate 17. Some of the particles of the beam 31 striking the multi-aperture plate 17 pass through the latter through the openings 19 in the second multi-aperture plate 17, while others are absorbed by the second multi-aperture plate 17 and do not pass through the openings 19. The particles of the beam 31 that pass through the second multi-aperture plate through the openings 19 thereof form a multiplicity of particle beams 33 in the beam path downstream of the second multi-aperture plate 17.

Each of the particle beams 33 successively passes through the first particle lens 21, the second particle lens 22 and the third particle lens 23 before it strikes the first multi-aperture plate 13. Some of the particles of each of the particle beams 33 pass through one of the openings 15 in the first multi-aperture plate 13 and form one of the particle beams 3 in the beam path downstream of the first multi-aperture plate 13. Other particles of each of the particle beams 33 strike the multi-aperture plate 13 and are absorbed thereby without passing through one of the openings 15 in the first multi-aperture plate 13.

A stop 35 can be disposed in the beam path upstream or downstream of the first multi-aperture plate 13, the stop having an opening 36 through which all beams 3 pass and an electric potential that differs from the potential of the first multi-aperture plate 13 being able to be applied to the opening by the controller 27 in order to produce an electric field between the first multi-aperture plate 13 and the stop 35. Such an electric field can have a focusing effect on the individual particle beams 3 in each case and can contribute to form the beam foci 323, which are imaged by the objective lens 102 on the surface 101 of the object 7.

It is desirable for the particle beams to be formed with a predetermined divergence or convergence in the beam path downstream of the first multi-aperture plate 13. In the illustration of FIG. 2, the particle beams 3 form a bundle of parallel beams 3 in the beam path downstream of the first multi-aperture plate 13. In order to achieve this, the particle beams 33 striking the first multi-aperture plate 13 is incident on the first multi-aperture plate 13 with an appropriate convergence or divergence. This convergence or divergence can be set by way of the setting of the excitations supplied to the particle lenses 21, 22 and 23.

The particle beams 3 formed in the beam path downstream of the first multi-aperture plate 13 are defined by the openings 15 in the first multi-aperture plate 13. This means that a cross section of each of the particle beams 3 directly downstream of the first multi-aperture plate 13 is determined by the cross section of the opening 15 through which the respective particle beam 3 passes.

Similarly, the beams 33 in the beam path downstream of the second multi-aperture plate 17 are defined by the openings 19 in the second multi-aperture plate 17.

The change in the excitation of the fourth particle lens 24 leads to a change in the divergence of the particle beam 31 upon incidence on the second multi-aperture plate 17. Since the change in the divergence of the beam 31 upon incidence on the second multi-aperture plate 17 is carried out in the beam path upstream of the second multi-aperture plate 17, i.e., at a distance from the latter, changing the divergence of the particle beam 31 also changes the size of the area of the second multi-aperture plate 17 that is illuminated by the particle beam 31. FIG. 2 illustrates a principal plane 44 of the fourth particle lens 24 as a plane orthogonal to an optical axis 47, the plane having a distance from the second multi-aperture plate 17.

As the area illuminated on the second multi-aperture plate 17 by the particle beam 31 changes, there is also a change in the beam currents of the particle beams 33 passing through the openings 19 in the second multi-aperture plate 17 when the beam current of the particle beam 31 remains unchanged. Furthermore, the beam currents of the particle beams 33 passing through the openings 15 in the first multi-aperture plate 13 change in accordance with the beam currents of the particle beams 33 striking the first multi-aperture plate 13. Consequently, it is evident that the beam currents of the particle beams 3 produced by the apparatus 300 can be altered by changing the excitation of the fourth particle lens 24. However, changing the beam currents of the particle beams 3 is accompanied by a change in the divergence with which the particle beam 31 strikes the second multi-aperture plate 17 and with which the particle beams 33 are likewise formed in the beam path downstream of the second multi-aperture plate 17. However, as explained above, the divergence of the particle beams 3, which are formed downstream of the first multi-aperture plate, should remain unchanged. This can be achieved by changing the excitations of the first, second and third particle lenses 21, 22 and 23 by the controller 27. The possibility of changing the three excitations of the three particle lenses 21, 22 and 23 offers three degrees of freedom for influencing the particle beams 33.

A first of these degrees of freedom is used to change the divergence of the particle beams 33 in the beam path downstream of the second multi-aperture plate 17 in such a way that the particle beams 33 are incident on the first multi-aperture plate 13 with the divergence desired for the divergence of the particle beams 3 in the beam path downstream of the first multi-aperture plate 13.

A second degree of freedom is used to set the spacings between the particle beams 33, with which the latter are incident on the first multi-aperture plate 13. These spacings should correspond to the spacings between the openings 15 in the first multi-aperture plate 13 such that particles of each of the particle beams 33 also pass through a corresponding opening 15 in the first multi-aperture plate 13.

A third degree of freedom is used for the following reason: If the particle beams 33 pass through the particle lenses 21, 22 and 23 and if one of these lenses is a magnetic particle lens, the magnetic field provided by the particle lens leads to the particle beams respectively extending along a spiral trajectory within the magnetic field. This means that particle beams 33 that extend in the plane of the drawing just below the second multi-aperture plate 17 in the illustration of FIG. 2 are twisted out of the plane of the drawing of FIG. 2 after passing through one of the particle lenses 21, 22 and 23 and do not strike the opening 15 in the first multi-aperture plate 13 that is provided for the particle beam 33 and situated in the plane of the drawing.

The third degree of freedom is therefore used to set the twist of the particle beams 33 about the optical axis 47 provided by all particle lenses 21, 22 and 23 in such a way that the particle beams 33 strike the openings 15, provided therefor, in the first multi-aperture plate 13 and form the particle beams 3 provided in the beam path downstream of the first multi-aperture plate 13. Therefore, the excitations of the particle lenses can be set in such a way that the particle beams 3 illustrated in FIG. 2 pass through the openings 15 in the first multi-aperture plate 13 in directions that lie in the plane of the drawing of FIG. 2. Expressed more generally, the particle beams pass through the openings 15 in the first multi-aperture plate 13 in directions that lie in planes that contain the optical axis 47 of the first, second and third particle lens 21, 22, 23 and a center of the opening 15 in the first multi-aperture plate 13 through which the respective particle beam 3 passes.

The excitations of the three particle lenses 21 to 23 disposed between the first multi-aperture plate 13 and the second multi-aperture plate 17 can be set in such a way that the lens system made of these three particle lenses 21 to 23 has a source-side focus, which lies in the vicinity of the particle source 11. Advantageously, but not necessarily, the source-side focus of the lens system consisting of the particle lenses 21 to 23 coincides with the position of the particle source 11. What this can achieve is that the openings 15 in the first multi-aperture plate 13 are irradiated by collimated or virtually collimated particle beams and the particle beams 3 generated by the first multi-aperture plate 13 emerge in telecentric fashion from the first multi-aperture plate 13. The change in the beam currents of the particle beams 3 passing through the openings in the first multi-aperture plate 13 can be implemented by changing the excitation of the fourth particle lens 24. The fourth particle lens 24 is disposed very close to the particle source 11 and hence very close to the source-side focus of the lens system consisting of the three particle lenses 21 to 23 disposed between the first multi-aperture plate 13 and the second multi-aperture plate 17. In order to exactly maintain the telecentricity of the particle beams 3 when changing the beam currents in the particle beams 33, it is desirable to change the excitations of the lens system made of the three particle lenses 21 to 23.

Moreover, the excitations of the three particle lenses 21 to 23 disposed between the first multi-aperture plate 13 and the second multi-aperture plate 17 can be varied in such a way that the common source-side focus of the lens system consisting of these three particle lenses 21 to 23 remains stationary but, at the same time, there is a change in the distance of the principal plane of the lens system consisting of these three particle lenses 21 to 23 from their source-side focus and hence from the particle source 11. As a result, it is possible to vary the spacing (pitch) between the particle beams 33 upon incidence on the first multi-aperture plate 13 without altering the telecentricity of the particle beams 33 upon incidence on the first multi-aperture plate 13. The excitation changes used for the displacement of the principal plane of the lens system consisting of the three particle lenses 21 to 23 can be distributed here among the three particle lenses 21 to 23—should some of the particle lenses 21 to 23 be embodied as magnetic lenses—in such a way that there is no additional rotation of the particle beams 33.

Overall, the beam currents of the particle beams 33, the telecentricity thereof upon incidence of the particle beams 33 on the first multi-aperture plate 13 and the spacings among one another (the pitch) can be varied independently of one another as a result of the described arrangement and the described choice of the excitations of the four particle lenses 21 to 24, without generating rotation of the totality of the particle beams 33 relative to the first multi-aperture plate 13.

The apparatus 300 further includes a first stigmator 41 which is disposed in the beam path between the second multi-aperture plate 17 and the first multi-aperture plate 13. The controller 27 is configured to supply the first stigmator 41 with an adjustable excitation. The apparatus further includes a second stigmator 42 which is disposed in the beam path between the first stigmator 41 and the first multi-aperture plate 13. The controller 27 is configured to supply the second stigmator 42 with an adjustable excitation.

The stigmators 41 and 42 provide multi-pole fields that depend on the excitations of the the stigmators and that influence the bundle of particle beams 33 passing through the stigmators 41 and 42 in order to influence the pattern of the arrangement of impingement locations of the particle beams 33 in the plane of the first multi-aperture plate 13 and, in particular, to compensate possible imaging aberrations of the first, second or third particle lens 21, 22, 23. As a result, the angle at which the particle beams 3 strike the object 7 can be altered by way of suitable actuation of the stigmators 41 and 42. In order furthermore to compensate further aberrations of the optical unit, such as of the objective lens 102, for example, a further stigmator, in addition to the two stigmators 41 and 42, can be disposed upstream or downstream of the first multi-aperture plate 13, the further stigmator providing further degrees of freedom for influencing the particle beams. In order to obtain even further degrees of freedom, one or more beam deflectors, for example, can be disposed upstream or downstream of the first multi-aperture plate 13 and the stigmators themselves may also be operated as deflectors.

In particular, dipole fields that produce a common deflection that is uniform for all particle beams 33 can be superposed on the stigmators 41, 42 in addition to the excitations used for the correction of imaging aberrations of the first, second and third particle lens 21, 22 and 23 and/or for the correction of imaging aberrations of the subsequent lens system. As a result, the angle between the particle beams 33 and the plane of the first multi-aperture plate 13, and hence the angle at which the particle beams 33 are incident on the first multi-aperture plate 13, can be varied. Furthermore, a dipole field superposed on the stigmator excitation of the first stigmator 41 may have an inverse polarity to a dipole field superposed on the stigmator excitation of the second stigmator 42. As a result, the positions at which the particle beams 33 are incident on the first multi-aperture plate 13 can be varied in addition to the angle at which the particle beams 33 are incident on the first multi-aperture plate 13.

Moreover—or as an alternative to the first multi-aperture plate 13—a multi-deflector array can be disposed in the plane 325 no longer illustrated in FIG. 2 (see FIG. 1), the beam foci being generated in the plane. Such a multi-deflector array has an opening for each of the particle beams 33. Two, three, four, eight or more electrodes are disposed around each of these openings, electric potentials being able to be applied to the electrodes independently of one another such that the deflection experienced by each particle beam is independently adjustable and variable for each particle beam. Using such a multi-deflector array, it is possible to individually set the angles of incidence of the particle beams 3 on the sample 7. Such a multi-deflector array may form the first multi-aperture plate 13 or may be present in addition to the first multi-aperture plate 13. In the latter case, a further lens system made of three particle lenses, the excitations of which are individually adjustable, should be disposed between the first multi-aperture plate 13 and the multi-deflector array. A suitable excitation of the lenses of this further lens system, the excitation being matched to one another, can set the telecentricity of the particle beams, the distance of the particle beams from one another (pitch) and the orientation of the particle beams relative to the openings of the multi-deflector array (rotation) upon incidence of the particle beams on the multi-deflector array independently of one another—as described above.

What is claimed is:

1. An apparatus, comprising:
a particle source;
a first multi-aperture plate comprising a multiplicity of openings;
a second multi-aperture plate comprising a multiplicity of openings, the second multi-aperture plate disposed in a beam path of the apparatus between the particle source and the first multi-aperture plate;
a first particle lens disposed in the beam path between the second and first multi-aperture plates;
a second particle lens disposed in the beam path between the first particle lens and the first multi-aperture plate;
a third particle lens disposed in the beam path between the first and second particle lenses; and
a controller configured to supply the first particle lens with an adjustable excitation, to supply the second particle lens with an adjustable excitation, and to supply the third particle lens with an adjustable excitation.

2. The apparatus of claim 1, wherein the particle source is configured to generate particles that pass through the multiplicity of openings in the second multi-aperture plate during the operation of the apparatus.

3. The apparatus of claim 2, wherein the particles generated by the particle source strike the second multi-aperture plate as a divergent beam.

4. The apparatus of claim 3, wherein the controller is configured to set the excitations of the first, the second and the third particle lenses so that particles that pass through the multiplicity of openings in the second multi-aperture plate pass through the multiplicity of openings in the first multi-aperture plate and define the multiplicity of particle beams in the beam path downstream of the second multi-aperture plate.

5. The apparatus of claim 4, wherein diameters of the openings in the first multi-aperture plate and diameters of the openings in the second multi-aperture plate are matched to each other so that a first portion of the particles passing through the multiplicity of openings in the second multi-aperture plate also passes through the openings in the first multi-aperture plate and so that a second portion of the particles passing through the multiplicity of openings in the second multi-aperture plate strikes the first multi-aperture plate and does not pass through the openings in the first multi-aperture plate.

6. The apparatus of claim 5, wherein:
the first, second and third particle lenses have a common optical axis which passes through the first multi-aperture plate;
the controller is configured to set the excitations of the first, the second and the third particle lenses so that each of the particle beams passes through the opening in the first multi-aperture plate in a direction that lies in a plane containing the common optical axis and a center of the opening in the first multi-aperture plate which the particle beam passes through.

7. The apparatus of claim 6, wherein the controller is configured to set the excitations of the first, the second and the third particle lenses so that each of the particle beams passes through the opening in the first multi-aperture plate in a direction that is oriented parallel to the common optical axis.

8. The apparatus of claim 1, further comprising a first stigmator disposed in the beam path between the second and first multi-aperture plates, wherein the controller is configured to supply the first stigmator with an adjustable excitation.

9. The apparatus of claim 8, further comprising a second stigmator disposed in the beam path between the first stigmator and the first multi-aperture plate, wherein the controller is configured to supply the second stigmator with an adjustable excitation.

10. The apparatus of claim 9, wherein the controller is configured to superpose dipole-generating excitations on the adjustable excitations of at least one member selected from the group consisting of the first stigmator and the second stigmator.

11. The apparatus of claim 1, further comprising a fourth particle lens disposed in the beam path between the particle source and the second multi-aperture plate, wherein the controller is further configured to supply the fourth particle lens with an adjustable excitation.

12. The apparatus of claim 11, wherein the controller is configured to provide the excitations of the first, second, third and fourth particle lenses matched to each other and to vary the excitations so that distances between the particle beams incident on the first multi-aperture plate after having passed through the second multi-aperture plate are variable.

13. The apparatus of claim 12, wherein the controller is configured to provide the excitations of the first, second, third and fourth particle lenses matched to each other and to vary the excitations so that distances between the particle beams incident on the first multi-aperture plate after having passed through the second multi-aperture plate and beam currents of the particle beams passing through the first multi-aperture plate are variable independently of each other.

14. The apparatus of claim 13, wherein the controller is configured to provide the excitations of the first, second, third and fourth particle lenses matched to each other and to vary the excitations in such a way that distances between the particle beams incident on the first multi-aperture plate after having passed through the second multi-aperture plate, beam currents of the particle beams passing through the first multi-aperture plate and a telecentricity of the particle beams passing through the first multi-aperture plate are variable independently of each other.

15. The apparatus of claim 1, wherein the particles generated by the particle source strike the second multi-aperture plate as a divergent beam.

16. The apparatus of claim 15, wherein the controller is configured to set the excitations of the first, the second and the third particle lenses so that particles that pass through the multiplicity of openings in the second multi-aperture plate pass through the multiplicity of openings in the first multi-aperture plate and define the multiplicity of particle beams in the beam path downstream of the second multi-aperture plate.

17. The apparatus of claim 16, wherein the controller is configured to set the excitations of the first, the second and the third particle lenses so that particles that pass through the multiplicity of openings in the second multi-aperture plate pass through the multiplicity of openings in the first multi-aperture plate and define the multiplicity of particle beams in the beam path downstream of the second multi-aperture plate.

18. The apparatus of claim 17, wherein diameters of the openings in the first multi-aperture plate and diameters of the openings in the second multi-aperture plate are matched to each other so that a first portion of the particles passing through the multiplicity of openings in the second multi-aperture plate also passes through the openings in the first multi-aperture plate and so that a second portion of the particles passing through the multiplicity of openings in the second multi-aperture plate strikes the first multi-aperture plate and does not pass through the openings in the first multi-aperture plate.

19. A system, comprising:
an apparatus according to claim 1; and
an objective lens configured to focus the particle beams on an object.

20. The system of claim 19, further comprising a detector arrangement configured to detecting signals generated by the particle beams at the object.
